(19) United States
(12) Patent Application Publication
(10) Pub. No.: US 2026/0305503 A1
(43) Pub. Date: Oct. 1, 2026

(54) CASCODE DEVICE PACKAGE WITH DSDB BJT AND FETS

(71) Applicant: IDEAL POWER INC., Austin, TX (US)

(72) Inventors: Sulav PARAJULI, Austin, TX (US); Jiankang BU, Austin, TX (US); Ruiyang YU, Austin, TX (US); Mudit KHANNA, Austin, TX (US)

(73) Assignee: IDEAL POWER INC., Austin, TX (US)

(21) Appl. No.: 19/576,389

(22) Filed: Mar. 24, 2026

Related U.S. Application Data
(60) Provisional application No. 63/781,635, filed on Apr. 1, 2025.

(51) Int. Cl. H10W 90/00; H03K 17/60; H03K 17/687; H10W 70/40

(52) U.S. Cl. CPC H10W 90/811; H03K 17/60; H03K 17/6871; H10W 70/458; H10W 70/464

(57) ABSTRACT

A semiconductor package integrates a double-sided double-base bipolar junction transistor (DSDB-BJT), cascode field-effect transistors (FETs), and driver FETs. The DSDB-BJT features first and second bases and first and second collector-emitter terminals, enabling bidirectional current flow. Cascode FETs are coupled to the collector-emitter terminals, while driver FETs control the bases. Integration within a single package significantly reduces loop inductance, minimizing transient voltages and current slew rates that can damage components. The package supports configurations such as double active metal brazing (AMB) and single AMB, offering double-sided cooling and cost efficiency. External pin connections are provided, and the package is mountable on a printed circuit board.

### CROSS-REFERENCE TO RELATED APPLICATIONS

This application claims the benefit of U.S. Provisional Patent Application 63/781,635 entitled “CASCODE DEVICE PACKAGE WITH DSDB BJT AND FETS”, filed Apr. 1, 2025, the entire disclosure of which is incorporated herein by reference.

### BACKGROUND

This disclosure is directed to semiconductor devices, and more particularly, to packages containing semiconductor devices for handing high voltages and high currents.

One failure mode of power semiconductor devices is known as “desaturation.” That is, when excess current is carried through a power semiconductor device, the device may be unable to maintain a low on-state voltage drop, which leads to desaturation. In related-art devices and systems, a gate driver provides voltage and currents to turn on and turn off the device, and the gate driver may be charged with sensing when desaturation occurs. When desaturation occurs, the gate drive may make the power semiconductor device non-conductive to reduce or avoid damage to itself or downstream devices.

### SUMMARY

A circuit for bidirectional power switching includes a double-sided double-base bipolar junction transistor having a first base, a second base, a first collector-emitter terminal, and a second collector-emitter terminal, a first field-effect transistor (FET) coupled to the first collector-emitter terminal, and a second FET coupled to the second collector-emitter terminal. The double-sided double-base bipolar junction transistor, the first FET, and the second FET are integrated within a single package.

A system includes a controller configured to generate a plurality of control signals and a bi-directional power switch coupled to receive the plurality of control signals. The bi-directional power switch is implemented in a single electronic package that includes a double-sided double-base bipolar junction transistor having a first base, a second base, a first collector-emitter terminal, and a second collector-emitter terminal, a first field-effect transistor (FET) electrically coupled between the first collector-emitter terminal and a first external pin of the electronic package, and a second FET electrically coupled between the second collector-emitter terminal and a second external pin, wherein the first FET and the second FET are coupled in a cascode configuration with the double-sided double-base bipolar junction transistor. The controller is configured to generate the plurality of control signals to control respective states of the first FET, the second FET, and the double-sided double-base bipolar junction transistor. The bi-directional power switch is configured to operate in one of a plurality of modes depending on respective states of ones of the plurality of control signals.

An electronic circuit package includes a package body including a plurality of external terminals, a double-sided double-base bipolar junction transistor disposed within the package body, the transistor having a first base, a second base, a first collector-emitter terminal, and a second collector-emitter terminal, a first field-effect transistor (FET) disposed within the package body and electrically coupled between the first collector-emitter terminal and a first external terminal of the plurality of external terminals, a second FET disposed within the package body and electrically coupled between the second collector-emitter terminal and a second external terminal of the plurality of external terminals, and a first substrate and a second substrate disposed within the package body. The double-sided double-base bipolar junction transistor is located in a region of overlap between the first substrate and the second substrate.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

For a detailed description of example embodiments, reference will now be made to the accompanying drawings.

FIG. 1 shows an example switch assembly according to the principles of the present disclosure.

FIG. 2 shows an example bidirectional switch according to the principles of the present disclosure.

FIG. 3 shows a partial functional block diagram, partial electrical schematic of an example switch assembly according to the principles of the present disclosure.

FIG. 4 shows a schematic of an electronic circuit integrated into a single package according to the principles of the present disclosure.

FIGS. 5A and 5B show side and top views of one embodiment of a package integrating an electronic circuit according to the principles of the present disclosure.

FIG. 6 shows inductance loops in one embodiment of an electronic circuit integrated into the package of FIGS. 5A and 5B.

FIGS. 7A and 7B show side and top views of another embodiment of a package integrating an electronic circuit.

FIG. 8 shows inductance loops of an embodiment of an electronic circuit integrated into the package of FIGS. 7A and 7B.

FIG. 9 show an example of a computing device in which the disclosed circuitry may be implemented.

### DEFINITIONS

Various terms are used to refer to particular system components. Different companies may refer to a component by different names – this document does not intend to distinguish between components that differ in name but not function. In the following discussion and in the claims, the terms “including” and “comprising” are used in an open-ended fashion, and thus should be interpreted to mean “including, but not limited to… .” Also, the term “couple” or “couples” is intended to mean either an indirect or a direct connection. Thus, if a first device is coupled to a second device, that connection may be through a direct connection or through an indirect connection via other devices and connections.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate that the recited referent may be plural.

“About” in reference to a recited parameter shall mean the recited parameter plus or minus ten percent (+/- 10%) of the recited parameter.

“Assert” shall mean creating or maintaining a first predetermined state of a Boolean signal. Boolean signals may be asserted high or with a higher voltage, and Boolean signals may be asserted low or with a lower voltage, at the discretion of the circuit designer. Similarly, “de-assert” shall mean creating or maintaining a second predetermined state of the Boolean, opposite the asserted state.

“FET” shall mean a field effect transistor, such as a junction-gate FET (JFET) or metal-oxide-silicon FET (MOSFET).

“Closing” in reference to an electrically-controlled switch (e.g., a FET) shall mean making the electrically-controlled switch conductive. For example, closing a FET used as an electrically-controlled switch may mean driving the FET to the fully conductive state.

“Opening” in reference to an electrically-controlled switch (e.g., a FET) shall mean making the electrically-controlled switch non-conductive. Leakage current shall not negate the status of an electrically-controlled switch being non-conductive.

“DSDB-BJT” shall mean a double-sided double-base (DSDB) bipolar junction transistor (BJT) having base and collector-emitter on a first side of a drift region, and a distinct and separate base and collector-emitter on a second side of the drift region, opposite the first side. The drift region may be continuous, or the drift region may comprise an upper drift region associated with the upper base and upper collector-emitter, and a lower drift region associated with the lower base and lower collector-emitter.

“Collector-emitter” of a bipolar junction transistor shall mean a region of the bipolar junction transistor through which main load current flows. For purposes of this specification and claims, the designation as a collector-emitter is independent of the underlying device physics within the bipolar junction transistor. For example, for a double-sided double-base PNP transistor, the main load current may flow from an upper P-type region, through the bulk N-type drift region, and then out the lower P-type region, and when so used the upper P-type region and the lower P-type region are considered collector-emitters. However, in other cases, such as described in co-pending and commonly assigned U.S. App. 18/483,939 filed October 10, 2023 and titled “Methods and Systems of Operating a PNP Bi-Directional Double-Base Bipolar Junction Transistor,” the main load current may flow from an upper N-type region, through the bulk N-type drift region, and then through the lower N-type region, and when so used the upper and lower N-type regions are considered collector-emitters.

“Base” of a bipolar junction transistor shall mean a region of the bipolar junction transistor through which control current flows, the control current distinct from the main load current. For purposes of this specification and claims, the designation as a base is independent of the underlying device physics within the bipolar junction transistor. For example, for a double-sided double-base PNP transistor, the control current may flow into an upper N-type region or a lower N-type region, and when so used the upper N-type region and the lower N-type region are considered bases. However, in other cases, such as described in co-pending and commonly assigned U.S. App. 18/483,939 noted above, the control current may flow into an upper P-type region or a lower P-type region, and when so used the upper and lower P-type regions are considered bases.

“Upper” in reference to component (e.g., upper collector-emitter, upper base) shall not be read to imply a location of the recited component with respect to gravity. Upper may be derived from location of the device in an example drawing.

“Lower” in reference to a component (e.g., upper collector-emitter, upper base) shall not be read to imply a location of the recited component with respect to gravity. Lower may be derived from location of the device in an example drawing.

The terms “input” and “output” when used as nouns refer to connections (e.g., electrical, software), and shall not be read as verbs requiring action. For example, a timer circuit may define a clock output. The example timer circuit may create or drive a clock signal on the clock output. In systems implemented directly in hardware (e.g., on a semiconductor substrate), these “inputs” and “outputs” define electrical connections. In systems implemented in software, these “inputs” and “outputs” define parameters read by or written by, respectively, the instructions implementing the function.

“Controller” shall mean, alone or in combination, individual circuit components, an application specific integrated circuit (ASIC), a microcontroller with controlling software, a reduced-instruction-set computing (RISC) with controlling software, a digital signal processor (DSP), a processor with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various embodiments of the disclosure. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

A DSDB-BJT may be used to implement a switching circuit for various power applications, such as a switching circuit for power applications. The switching circuit may include a cascode configuration having cascode FETs, one each coupled to the emitter terminals of the DSDB-BJT. Driver FETs may also be used to drive the dual bases of the DSDB-BJT. The DSDB-BJT, cascode FETs, and driver FETS may be separately mounted on a printed circuit board (PCB). However, this can lead to high loop inductances in the circuit for some applications, leading to high current slew rate (di/dt) and high transient voltages. The high current slew rate and high transient voltage can burn various ones of the devices mentioned above, such as the DSDB-BJT during certain operations, such as turning off the switching circuit. Example overcurrent protection techniques are described in U.S. Patent Application No. 19/464,773, filed on Jan. 30, 2026, which claims the benefit of U.S. Provisional Patent Application No. 63/759,314, filed Feb. 17, 2025, both of which are incorporated herein by reference in their entirety.

Some reduction of the loop inductances is possible by moving the various devices closer to one another on the PCB. However, these reductions are limited. The present disclosure makes use of the insight that, if each of these devices could be implemented in the same package, more significant reductions of the loop inductance could be realized. Accordingly, the present disclosure is directed to an electronic circuit and package in which the DSDB-BJT, the cascode FETs, and driver FETs are all integrated into a single package. The package may be mountable on a printed circuit board and provide pin connections for the various terminals of the devices thereon.

A package according to the disclosure may be implemented in various ways. In one embodiment, a package may be implemented in a double active metal brazing (AMB) configuration. In another embodiment, the package may be implemented in a single AMB configuration. In some embodiments, the design may make it possible to use a double-sided cooling capability. Some embodiments may utilize a design having a single AMB configuration, thereby reducing cost.

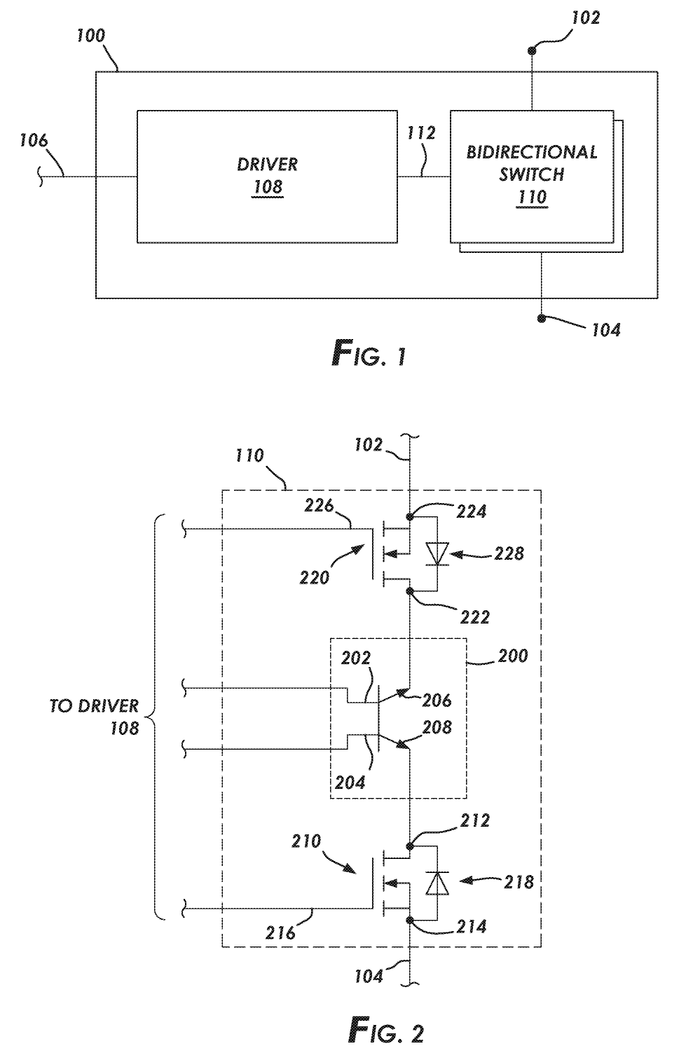

FIG. 1 shows an example switch assembly 100. In particular, the example switch assembly 100 defines an upper terminal 102, a lower terminal 104, and a control input or control terminal 106. Internally, the example switch assembly 100 includes a driver 108 and a bidirectional switch 110. The driver 108 defines the control terminal 106, and the driver 108 is coupled to the bidirectional switch 110, as shown by connections 112. The connections 112, though shown as a single connection, represent a plurality of electrical connections to the bidirectional switch 110 whose conductive state may vary. The driver 108 controls the conductive state of the bidirectional switch 110 by controlling the voltages/currents on the connections 112.

One example of the switch assembly 100 may include a single bidirectional switch 110. Another example switch assembly 100 may have two or more bidirectional switches 110, as illustrated in FIG. 1 by the “stacked” arrangement for the bidirectional switch 110. When multiple bidirectional switches 110 are present, the bidirectional switches 110 are electrically connected in parallel to share the main load current (forward or reverse). So as not to unduly complicate the specification, the discussion that follows assumes a single bidirectional switch 110. However, one having ordinary skill, and with the benefit of this disclosure, understands that the multiple bidirectional switches may be present depending on the designed current carrying capability of any specific switch assembly 100.

In some embodiments, bidirectional switch 110 may be implemented in a single electronic package. As will be discussed below, bidirectional switch may include a DSDB-BJT along with corresponding FETs arranged in a cascode configuration. Embodiments are further possible and contemplated in which the entirety of switch assembly 100, (including devices that implement driver 108) is implemented in a single electronic package. Details of such embodiments are discussed in further detail below beginning with the description of FIG. 4.

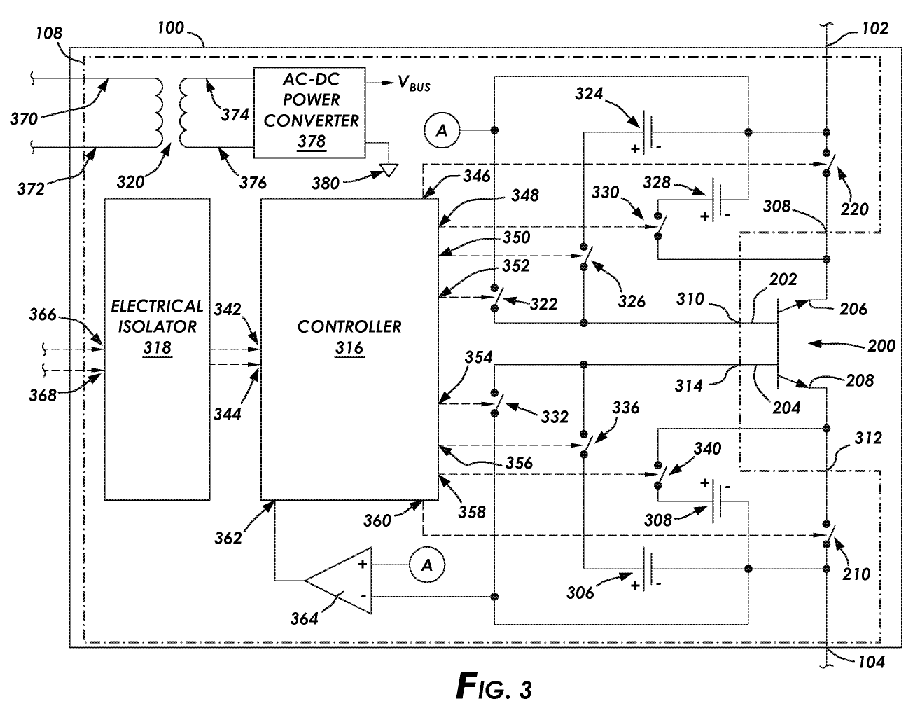

FIG. 2 shows a schematic of example bidirectional switch 110. In particular, the example bidirectional switch 110 includes a DSDB-BJT 200 that defines an upper base 202, a lower base 204, an upper collector-emitter 206, and a lower collector-emitter 208. The switch 110 further includes a lower cascode FET 210 with a drain 212 coupled to the lower collector-emitter 208, a source 214 coupled to the lower terminal 104, and a gate 216 coupled to the driver 108. A body diode 218 is intrinsic to the FET 210. Similarly, an upper cascode FET 220 has a drain 222 coupled to the upper collector-emitter 206, a source 224 coupled to the upper terminal 102, and a gate 226 coupled to the driver 108. The upper cascode FET also includes a body diode 228. This cascode structure allows voltage regulation and fast switching while preserving bidirectional current flow through the DSDB BJT 200. The various components of bidirectional switch 110, including DSDB-BJT 200, along with FETs 210 and 220, may be implemented within a single electronic package. Additional components may also be implemented in the same package, such as the driver FETs discussed below in reference to the embodiment of FIG. 4.

The driver 108 is coupled to the bidirectional switch 110 by a plurality of electrical connections. In the example of FIG. 2, the electrical connections to the driver 108 may comprise connections to: the gate 226 of the upper cascode FET 220; the upper collector-emitter 206; the upper base 202; the lower base 204; the lower collector-emitter 208; and the gate 216 of the lower cascode FET 210. The driver 108 controls states/modes of the bidirectional switch 110 by controlling the voltages/currents on the various connections. States of the bidirectional switch 110 include, but are not limited to, passive off, passive on, active on, alternative active on, pre-turn off, reverse recovery, and alternative reverse recovery states. Example control and operation of the bidirectional switch 110 and the various states are described in more detail in U.S. Pat. Application No. 18/583,188, filed on Feb. 21, 2024, the entire contents of which are incorporated herein by reference.

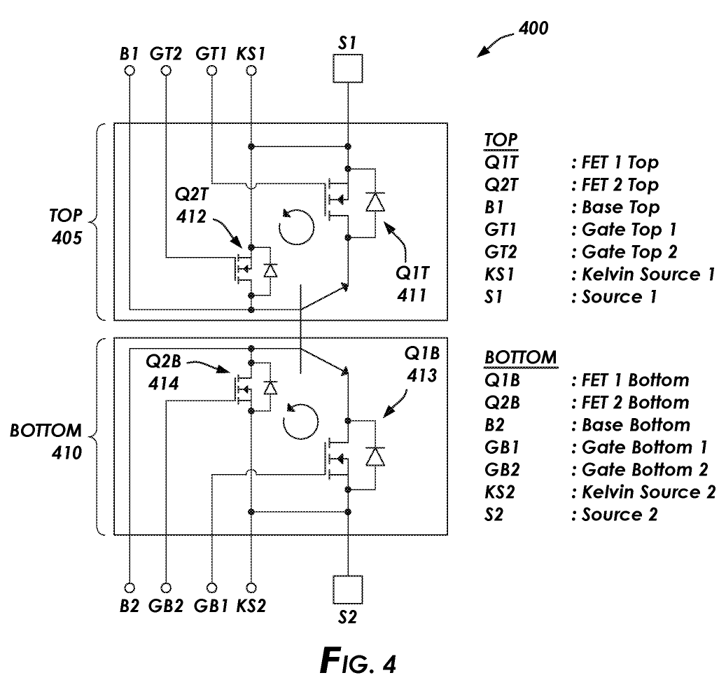

FIG. 3 shows a partial block diagram, partial electrical schematic of an example implementation of the switch assembly 100. In particular, the example switch assembly 100 comprises the example DSDB-BJT 200 and the driver 108. The DSDB-BJT 200 is shown by way of an example circuit symbol having two emitters and two bases. The circuit symbol shows the upper base 202, the lower base 204, the upper collector-emitter 206, and the lower collector-emitter 208. The example driver 108 defines an upper collector-emitter terminal 308 coupled to the upper collector-emitter 206, an upper conduction terminal 310 coupled to the upper base 204, a lower collector-emitter terminal 312 coupled to the lower collector-emitter 208, and a lower-conduction terminal 314 coupled to the lower base 204. As with the system discussed in FIG. 1, at least portions of the system shown in FIG. 3 may be implemented in a single integrated circuit package.

The example driver 108 comprises a controller 316, an electrical isolator 318, and an isolation transformer 320. In order to place the DSDB-BJT 200 in the various conduction and non-conduction modes, the example driver 108 includes a plurality of electrically-controlled switches and sources of charge carriers. In particular, the example driver 108 comprises a switch 322 that has its first lead coupled to the upper terminal 102, a second lead coupled to the upper base 202, and a control input coupled to the controller 316. The example switch 322 is shown as a single-pole, single-throw switch, but in practice the switch 322 may be a FET with the control input being a gate of the FET. Thus, when the switch 322 is made conductive by assertion of its control input, the upper base 202 is coupled to the upper terminal 102.

The driver 108 further comprises a source 324 illustratively shown as a battery. The source 324 has a negative lead coupled to the upper terminal 102. Another electrically-controlled switch 326 (hereafter just switch 326) has a first lead coupled to the positive terminal of the source 324, a second lead coupled to the upper base 202, and a control input coupled to the controller 316. The example switch 326 is also shown as a single-pole, single-throw switch, but in practice the switch 326 may be a FET with the control input being the gate of the FET. Thus, when the switch 326 is conductive, the source 324 is coupled between the upper terminal 102 and the upper base 202.

The driver 108 further comprises source 328 illustratively shown as a battery. The source 328 has a negative lead coupled to the upper terminal 102. Another electrically-controlled switch 330 (hereafter just switch 330) has a first lead coupled to the positive terminal of the source 328, a second lead coupled to the upper collector-emitter 206, and a control input coupled to the controller 316. The example switch 330 is also shown as a single-pole, single-throw switch, but in practice the switch 330 may be a FET with the control input being the gate of the FET. Thus, when the switches 322 and 330 are conductive, the source 328 is coupled between the upper base 202 and the upper collector-emitter 206 (e.g., reverse recovery for an externally applied voltage more positive at the lower terminal 104, or the alternative reverse recovery for the externally applied voltage more positive on the upper terminal 102).

The driver 108 further comprises the upper cascode FET 220. The upper cascode FET 220 is illustratively shown as a single-pole, single-throw switch. Thus, when the upper cacode FET 220 is made conductive, such as by assertion of its control input, the upper terminal 102 is coupled to the upper collector-emitter 206.

Turning now to lower side of the DSDB-BJT 200, the example driver 108 further comprises a switch 332 that has a first lead coupled to the lower terminal 104, a second lead coupled to the lower base 204, and a control input coupled to the controller 316. The example switch 332 is shown as a single-pole, single-throw switch, but in practice the switch 332 may be a FET with the control input being a gate of the FET. Thus, when the switch 332 is made conductive by assertion of its control input, the lower base 204 is coupled to the lower terminal 104.

The driver 108 further comprises the source 306 illustratively shown as a battery. The source 306 has a negative lead coupled to the lower terminal 104. Another electrically-controlled switch 336 (hereafter just switch 336) has a first lead coupled to the positive terminal of the source 306, a second lead coupled to the lower base 204, and a control input coupled to the controller 316. The example switch 336 is shown as a single-pole, single-throw switch, but in practice the switch 336 may be a FET with the control input being the gate of the FET. Thus, when the switch 336 is conductive, the source 306 is coupled between the lower terminal 104 and the lower base 204.

The example driver 108 further comprises the source 308 illustratively shown as a battery. The source 308 has a negative lead coupled to the lower terminal 104. Another electrically-controlled switch 340 (hereafter just switch 340) has a first lead coupled to the positive terminal of the source 308, a second lead coupled to the lower collector-emitter 208, and a control input coupled to the controller 316. The example switch 340 is shown as a single-pole, single-throw switch, but in practice the switch 340 may be a FET with the control input being the gate of the FET. Thus, when the switches 332 and 340 are conductive, the source 308 is coupled between the lower base 204 and the lower collector-emitter 208 (e.g., reverse recovery operation).

The example driver 108 further comprises the lower cascode FET 210. The lower cascode FET 210 is shown as a single-pole, single-throw switch. Thus, when the lower cascode FET 210 is conductive, such as by assertion of its control input, the lower terminal 104 is coupled to the lower collector-emitter.

The controller 316 defines control inputs 342 and 344, and control outputs 346, 348, 350, 352, 354, 356, 358, and 360 coupled to the control inputs of the upper cascode FET 220, switches 330, 326, 322, 332, 336, and 340, and the lower cascode FET 210, respectively. When the control input 342 is asserted, the controller 316 is designed and constructed to arrange the DSDB-BJT 200 for conduction from the upper terminal 102 to the lower terminal 104. Oppositely, when the control input 342 is de-asserted, the controller 316 is designed and constructed to arrange the DSDB-BJT 200 to block current flow from the upper terminal 102 to the lower terminal 104. Similarly, when the control input 344 is asserted, the controller 316 is designed and constructed to arrange the DSDB-BJT 200 for conduction from the lower terminal 104 to the upper terminal 102. Oppositely, when the control input 344 is de-asserted, the controller 316 is designed and constructed to arrange the DSDB-BJT 200 to block current flow from the lower terminal 104 to the upper terminal 102. When the control inputs 342 and 344 are both asserted, the controller 316 arranges the DSDB-BJT 200 for current flow in both directions (e.g., AC breaker service), and when the control inputs 342 and 344 are both de-asserted, the controller 316 blocks current flow in both directions.

The arrangement of the DSDB-BJT 200 to be non-conductive is dependent upon the polarity of the applied voltage. Thus, the example controller 316 may further define a polarity input 362 that receives a Boolean indication of the applied polarity. In the example driver 108, a comparator 364 has a first input coupled to the upper terminal 102 (the connection shown by bubble “A”) and a second input coupled to the lower terminal 104. The comparator 364 defines a compare output coupled to the polarity input 362. While FIG. 3 shows the first and second inputs coupled directly to the respective conduction terminals, in practice the voltage across the DSDB-BJT 200 when non-conductive may be large (e.g., 1200V) and thus each of the first and second inputs may be coupled to their respective conduction terminals by way of respective voltage divider circuits. In yet still further cases, the applied polarity may be determined by systems and devices external to the switch assembly 100, and a Boolean signal sent across the electrical isolator 318 to the polarity input 362.

Transitioning the DSDB-BJT 200 from being non-conductive, to conductive, and then back to non-conductive may be a multistep process. To implement the multistep process, the controller 316 may be individual circuit components, an application specific integrated circuit (ASIC), a microcontroller with controlling software, a reduced-instruction-set computing (RISC), a digital signal processor (DSP), a processor with controlling software, a programmable logic device (PLD), a field programmable gate array (FPGA), a programmable system-on-a-chip (PSOC), and/or combinations, configured to read the control inputs 342 and 344, read the polarity input 362, and drive control outputs to implement the mode transitions of the DSDB-BJT 200.

In example systems, the switch assembly 100 is electrically floated. In order to receive the control inputs 342 and 344 in the electrical domain of the switch assembly 100, the example driver 108 implements the electrical isolator 318. The example electrical isolator 318 may take any suitable form, such as optocouplers or capacitive isolation devices. Regardless of the precise nature of the electrical isolator 318, external control signals (e.g., Boolean signals) may be coupled to control inputs 366 and 368 of the electrical isolator 318. Either of the control inputs 366 or 368 may be the control terminal 106 illustratively presented in FIG. 1. The electrical isolator 318, in turn, passes the control signals through to the electrical domain of the switch assembly 100. In the example, the external control signals are passed through to become the control input 342 and 344 of the controller 316.

Turning now to the isolation transformer 320, various devices within the switch assembly 100 may use operational power. For example, the controller 316 may use a bus voltage and power to enable implementation of the various modes of operation of the DSDB-BJT 200. Further, the sources within system may be implemented as individual voltage sources in the form of switching power converters, or individual current sources also in the form of switching power converters. The switching power converters implementing the sources may use bus voltage and power. In order to provide operational power within the electrical domain of the switch assembly 100, the isolation transformer 320 is provided. External systems (not specifically shown) may provide an alternating current (AC) signal across primary leads 370 and 372 of the isolation transformer 320 (e.g., 15V AC). The isolation transformer 320 creates an AC voltage on secondary leads 374 and 376. The AC voltage on the secondary of the isolation transformer 320 may be provided to an AC-DC power converter 378, which rectifies the AC voltage and provides power by way of bus voltage V_{BUS} (e.g., 3.3V, 5V, 12V) with respect to a common or ground terminal 380. The power provided by the AC-DC power converter 378 may be used by the various components of the switch assembly 100. In other cases, multiple isolation transformers may be present (e.g., one for each side of the DSDB-BJT). Further still, a single isolation transformer with multiple secondary windings may be used. The discussion now turns to example arrangements for making the DSDB-BJT 200 conductive and/or non-conductive in the context of the switch assembly 100.

Consider, as an example, a situation in which the applied voltage has the positive polarity on the upper terminal 102. Further consider that the control input 366 applied to the electrical isolator 318 is de-asserted, and thus a control signal applied to the control input 342 of the controller 316 is de-asserted. Based on the de-asserted state of the control input 342, the controller 316 is designed and constructed to place the DSDB-BJT 200 in the non-conductive arrangement taking into account the applied polarity (e.g., as read by the controller 316 through the polarity input 362). Thus, in the example arrangement the upper cascode FET 220 is conductive, the lower cascode FET 210 is non-conductive and the switch 332 is conductive (passive off). In some examples, the upper cascode FET 220 is made conductive by the controller 316 asserting the control output 346. However, in other cases, the body diode of the upper cascode FET 220, and thus the conductivity of upper cascode FET 220, may be based, initially at least, on the applied voltage forward biasing the body diode of the FET. A similar arrangement and/or operation may exist for the lower cascode FET 210 when arranged for blocking current for the opposite polarity.

Still considering the example arrangement of the positive polarity at the upper terminal 102, now consider that the control signal applied to the control input 366 of the electrical isolator 318 is asserted, and thus the control signal applied to the control input 342 of the controller 316 is asserted. Based on the assertion, in the example switch assembly 100 the controller 316 may be designed and constructed to place the DSDB-BJT 200 directly into an active-on arrangement. To that end, the controller 316 may assert the control output 346 (if not already asserted) to make the upper cascode FET 220 conductive, assert the control output 350 to make the switch 326 conductive, assert the control output 360 to make the lower cascode FET 210 conductive, and de-assert or leave de-asserted the remaining control outputs. In yet still other cases, to place the DSDB-BJT 200 in the conductive state, the controller 316 may be designed and constructed to make the switch 326 conductive a predetermined period of time prior (e.g., from about 0.1 μs to 5 μs) to making the lower cascode FET 210. Making the switch 326 conductive prior to the making the lower cascode FET 210 conductive may charge the upper collector-emitter 206 to upper base 202 capacitance, making the DSDB-BJT 200 fully conductive more quickly once the lower cascode FET 210 is conductive. In some cases, the controller 316 may be designed and constructed to implement the alternative active-on arrangement, and thus controller 316 may also assert the control output 356 to couple the source 306 between the lower terminal 104 and the lower base 204.

Optionally, again with the positive polarity at the upper terminal 102, the controller 316 may be designed and constructed to take the DSDB-BJT 200 through an intermediate conductive arrangement before arriving at the active-on arrangement. For example, the controller 316 may momentarily place the DSDB-BJT 200 in the passive-on arrangement. When used, the passive-on arrangement may last a predetermined period (e.g., from about 0.1 μs to 5 μs).

In the active-on arrangement, and for the positive polarity at the upper terminal 102, the source 324 injects charge carriers into the upper base 202. Injecting charge carriers into the upper base 202 increases the number of charge carriers in the drift region of the DSDB-BJT 200, which lowers the V_{CEON} measured across the collector-emitters 206 and 208. In one example, the source 324 injecting charge carriers may lower the V_{CEON} to about 0.2V for about 30A to 100A of current flow through the collector-emitters 206 and 208. The source 324 may take any suitable voltage between and including 0.5V and 5.0V, in some cases between 0.6V and 1.5V.

Still referring to FIG. 3, and still considering the positive polarity on the upper terminal 102. Further consider that the control input 366 applied to the electrical isolator 318 transitions from asserted to de-asserted, and thus a control signal applied to the control input 342 of the controller 316 transitions from asserted to de-asserted. Based on the transition, the controller 316 is designed and constructed to place the DSDB-BJT 200 into the reverse recovery arrangement. To that end, the controller 316 de-asserts the control output 360 to make the lower cascode FET 210 non-conductive to interrupt the main load current through the DSDB-BJT 200, de-assert the control output 350 to make the switch 326 non-conductive, assert the control output 354 to make the switch 332 conductive to couple the lower base 204 to the lower terminal 104, and assert the control output 358 to make the switch 340 conductive to couple the source 308 between the lower base 204 and the lower collector-emitter 208. As previously mentioned, the reverse recovery arrangement may be implemented for a predetermined period of time, in some cases about 400 nanoseconds. Thereafter, the controller 316 may transition the DSDB-BJT 200 to a passive-off arrangement.

The example operation discussed with respect to FIG. 3 was with the positive polarity on the upper terminal 102. Again, however, the example DSDB-BJT 200 and the related driver 108 are symmetrical, and now understanding how to arrange the DSDB-BJT 200 into the various conductive and non-conductive states, control of current flow in the opposite direction directly follows.

FIG. 4 shows a schematic of an electronic circuit 400 integrated into in a single package. In the embodiment shown, the circuit includes a top portion 405 and a bottom portion 410, with a DSDB-BJT extending across these two portions. A base B1 and a first emitter of the DSDB-BJT are located on the top portion, while a base B2 and a second emitter of the DSDB-BJT are located on the bottom portion. A cascode circuit is formed between terminals S1 and S2 using devices Q1T 411 and Q1B 413 and the respective emitters of the DSDB-BJT to which they are coupled.

The circuit also includes a pair of driver devices Q2T 412 and Q2B 414, with Q2T 412 being coupled to the base B1 on the top portion and Q2B 414 coupled to the base B2 on the bottom portion. Driver Q2T 412 may be driven via terminal GT2, while terminal GB2 may be used to control driver Q2B 414. Terminal GT1 may be used to control Q1T 411, while terminal GB1 may be used to control Q1B 413. Biasing of Q2T 412 and Q2B 414 may be carried out via terminals KS1 and KS2, respectively.

By controlling the signal levels on the various terminals of Q1T 411, Q1B 413, Q2T 412, and Q2B 414, the circuit shown may be operated as a bidirectional switch between terminals S1 and S2. This switch may be utilized in various power applications, among other uses.

In the embodiment shown, loop inductances form through the cascode devices, their associated drivers, and associated portion of the DSDB-BJT. When the various devices shown here are mounted as discrete devices on a printed circuit board, high inductance values are the result. It is desirable to minimize these inductances, as high values thereof can lead to high values of a current slew rate and transient voltages. High transient voltages and high values of the current slew rate can in some cases burn various ones of the devices and render the circuit inoperable. While some loop inductance can be reduced by placing the devices closer together on the PCB, the reductions may not be sufficient to present the problems outlined above. In the present disclosure, significant reductions in the loop inductance are achieved by incorporating all the devices shown in the circuit of FIG. 4 into a single package. The package may be subdivided into a top portion and a bottom portion (as shown in FIG. 4) or, more generally, into a first portion and a second portion.

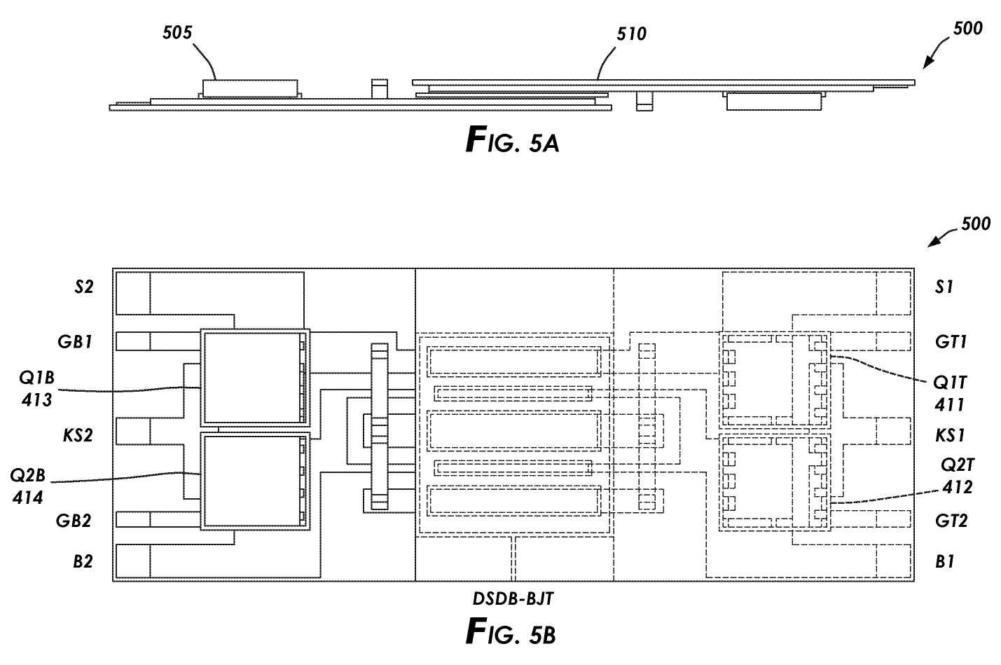

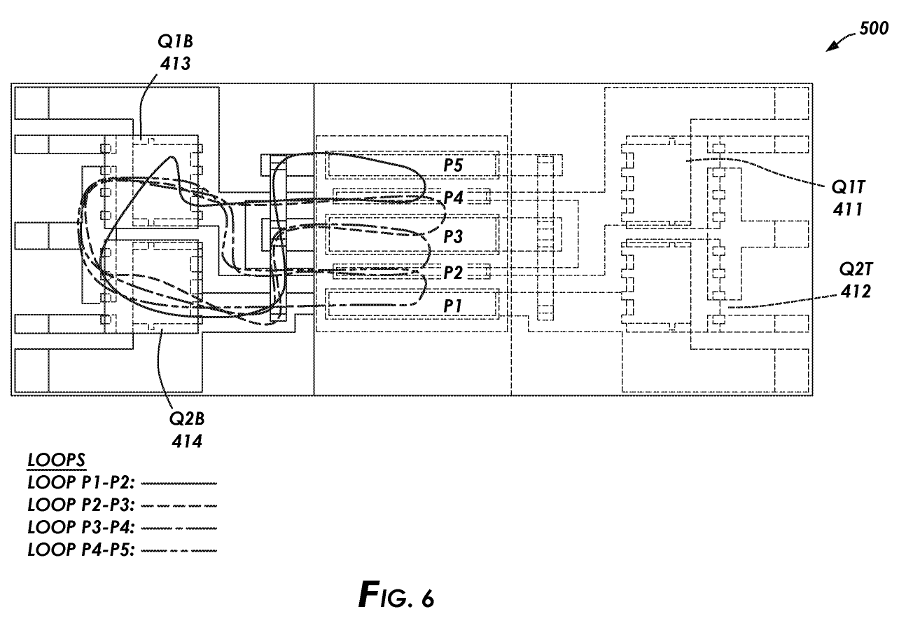

FIGS. 5A and 5B show side and top views of one embodiment of an electronic circuit package (e.g., an integrated circuit package). As shown in FIGS. 5A and 5B, the package includes a first portion 505 and a second portion 510. The first portion 505 includes the cascode device Q1B 413 and the driver device Q2B 414. The second portion 510 includes the cascode device Q1T 411 and driver device Q2T 412. A DSDB-BJT (in accordance with the various embodiments discussed above) is located where first portion 505 and second portion 510 are overlapping, with part located on first portion 505 and another part located on second portion 510. These portions may comprise substrates in which the devices are implemented.

By implementing each of the devices into a single package, the inductances discussed above may be significantly reduced, and thereby minimize the problem that might otherwise occur with higher inductances.

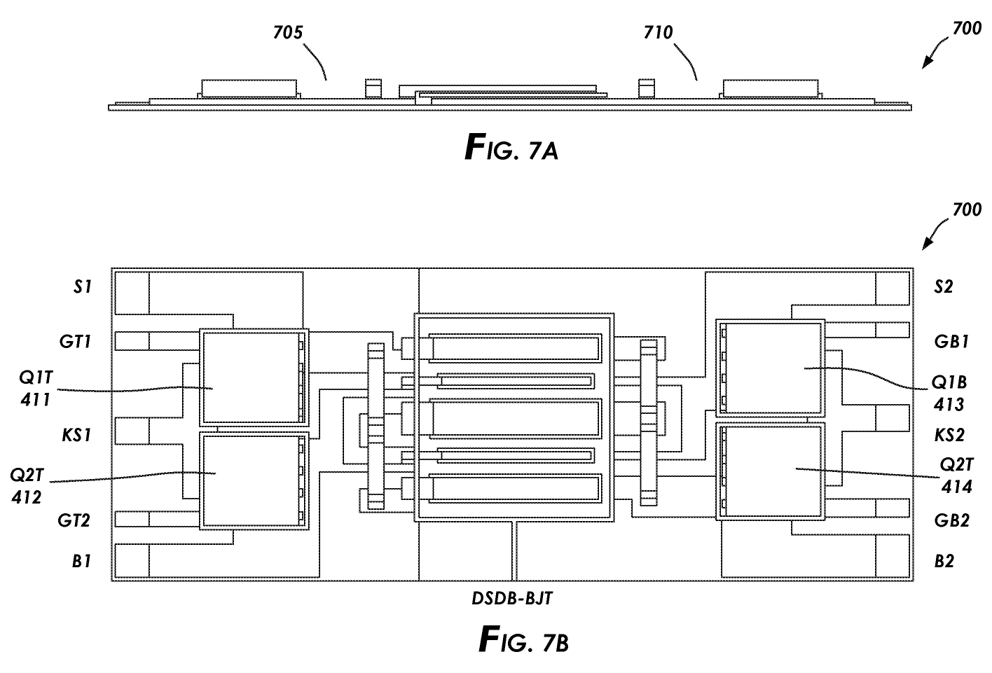

FIG. 6 shows some of the inductance loops in one embodiment of an electronic circuit integrated into the package 500 of FIGS. 5A and 5B. The loops in the embodiment shown are formed by the integrated cascode and driver devices, including Q1T 411, Q2T 412, Q1B 413, and Q2B 414, and illustrate the current paths that contribute to reducing inductance. The loop paths are defined as Loop P1-P2, Loop P2-P3, Loop P3-P4, Loop P4-P5, Loop P1-P4, and Loop P2-P5, and are used to characterize and estimate the loop inductance, which plays a significant role in reducing transient voltages and current slew rates. By integrating the various devices in a single electronic package the inductance in these loops may be significantly less than if some of the various devices (e.g., the FETs) were implemented as discreet components mounted on a PCB. This arrangement may thus allow for faster switching and improved performance in voltage handling.

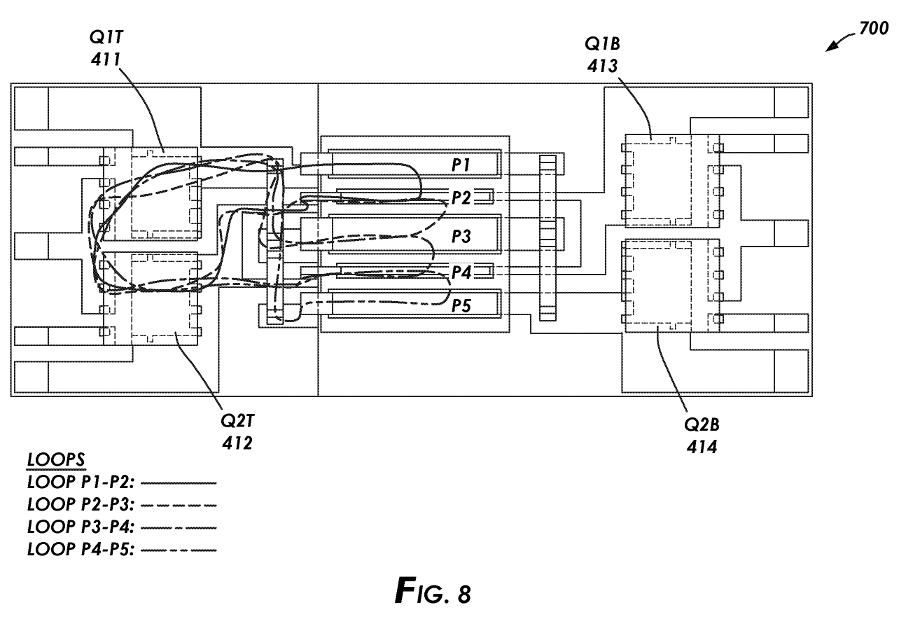

FIG. 7A and 7B show side and top views of another embodiment of a package 700 integrating an electronic circuit. In the embodiment shown, the package includes a first portion 705 and a second portion 710. However, this embodiment is not arranged in a top-bottom arrangement like the embodiment of FIGS. 5A and 5B. Instead, the portions 705 and 710 are arranged side-by-side, with the DSDB-BJT implemented in a such a manner to span a junction of these portions. Cascode device Q1T 411 and driver device Q2T 412 are implemented in portion 705, while cascode device Q1B 413 and driver device Q2B 414 are implemented in portion 710.

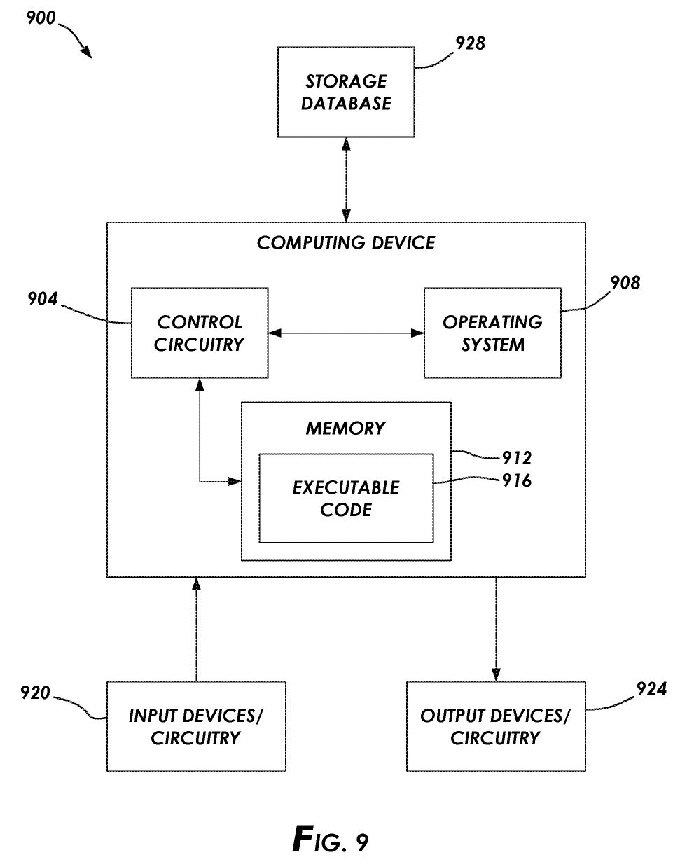

FIG. 8 shows some of the inductance loops of an embodiment of an electronic circuit integrated into the package 700 of FIGS. 7A and 7B. The loops may be formed by the integrated devices Q1T 411, Q2T 412, Q1B 413, and Q2B 414, and illustrate the current paths necessary for reducing inductance in this configuration. The reference points P1, P2, P3, P4, and P5 define the loop segments and paths, and are used to measure and characterize the loop inductance, ensuring the design achieves the desired performance improvements. The reduction in loop inductance achieved by this package design enables higher switching speeds, improved voltage handling, and greater reliability in various power applications.

FIG. 9 shows a block diagram of an example computing device 900 configured to implement functions of the systems and methods described herein according to the present disclosure. For example, one or more of the computing devices 900 may implement a bidirectional power switch, such as that discussed above with reference to FIGS. 1-8. The bidirectional power switch may be implemented within a single electronic circuit package that includes a DSDB-BJT and corresponding cascode FETs. Systems described herein may implement a single computing device, a plurality of computing devices, etc., configured to individually and/or collectively perform functions related to the systems and methods of the present disclosure.

The computing device 900 may include control circuitry 904 that may be, for example, one or more processors or processing devices, a central processing unit processor, an integrated circuit or any suitable computing or computational device, an operating system 908, memory 912, executable code 916, input devices or circuitry 920, and output devices or circuitry 924. The control circuitry 904 (or one or more controllers or processors, possibly across multiple units or devices) may be configured to implement functions of the systems and methods described herein. More than one of the computing devices 900 may be included in, and one or more of the computing devices 900 may act as the components of a system according to embodiments of the disclosure. Various components of the computing device 900 may be implemented with same or different circuitry, same or different processors or processing devices, etc.

The operating system 908 may be or may include any code segment (e.g., one similar to the executable code 916 described herein) configured and/or configured to perform tasks involving coordination, scheduling, arbitration, supervising, controlling or otherwise managing operation of the control circuitry 904 (e.g., scheduling execution of software programs or tasks or enabling software programs or other hardware modules or units to communicate). The operating system 908 may be a commercial operating system. The operating system 908 may be an optional component (e.g., in some embodiments, a system may include a computing device that does not require or include the operating system 908). For example, a computer system may be, or may include, a microcontroller, an application specific circuit (ASIC), a field programmable array (FPGA), network controller (e.g., CAN bus controller), associated transceiver, system on a chip (SOC), and/or any combination thereof that may be used without an operating system.

The memory 912 may be or may include, for example, Random Access Memory (RAM), read only memory (ROM), Dynamic RAM (DRAM), Synchronous DRAM (SD-RAM), a double data rate (DDR) memory chip, Flash memory, volatile memory, non-volatile memory, cache memory, a buffer, a short-term memory unit, a long-term memory unit, or other suitable memory units or storage units. The memory 912 may be or may include a plurality of memory units, which may correspond to same or different types of memory or memory circuitry. The memory 912 may be a computer or processor non-transitory readable medium, or a computer non-transitory storage medium, e.g., RAM.

The executable code 916 may be any executable code, e.g., an application, a program, a process, task, or script. The executable code 916 may be executed by the control circuitry 904, possibly under control of the operating system 908. Although, for the sake of clarity, a single item of the executable code 916 is shown, a system according to some embodiments of the disclosure may include a plurality of executable code segments similar to the executable code 916 that may be loaded into the memory 912 and cause the control circuitry 904 to carry out methods described herein. Where applicable, the terms “process” and “executable code” may be used interchangeably herein. For example, verification, validation and/or authentication of a process may mean verification, validation and/or authentication of executable code.

In some examples, the memory 912 may include non-volatile memory having the storage capacity of a storage system. In other examples, the computing device 900 may include or communicate with a storage system and/or database. Such a storage system may include, for example, flash memory, memory that is internal to, or embedded in, a micro controller or chip, a hard disk drive, a solid-state drive, a CD-Recordable (CD-R) drive, a Blu-ray disk (BD), a universal serial bus (USB) device or other suitable removable and/or fixed storage unit. Content may be stored in the storage system and loaded from the storage system into the memory 912 where it may be processed by the control circuitry 904.

The input circuitry 920 may be or may include any suitable input devices, components, or systems, e.g., physical sensors such as accelerometers, thermometers, microphones, analog to digital converters, etc., a detachable keyboard or keypad, a mouse, etc. The output circuitry 924 may include one or more (possibly detachable) displays or monitors, motors, servo motors, speakers and/or any other suitable output devices. Any applicable input/output (I/O) devices may be connected to the control circuitry 904. For example, a wired or wireless network interface card (NIC), a universal serial bus (USB) device, or external storage device may be included in the input circuitry 920 and/or the output circuitry 924. It will be recognized that any suitable number of input devices and output devices may be operatively connected to the control circuitry 904. For example, the input circuitry 920 and the output circuitry 924 may be used by a technician or engineer in order to connect to the control circuitry 904, update software, and the like.

Embodiments may include an article such as a computer or processor non-transitory readable medium, or a computer or processor non-transitory storage medium, such as for example memory, a disk drive, or USB flash memory, encoding, including or storing instructions (e.g., computer-executable instructions, which, when executed by a processor or controller, carry out methods disclosed herein), a storage medium such as the memory 912, computer-executable instructions such as the executable code 916, and a controller such as the control circuitry 904.

The storage medium may include, but is not limited to, any type of disk including magneto-optical disks, semiconductor devices such as read-only memories (ROMs), random access memories (RAMs), such as a dynamic RAM (DRAM), erasable programmable read-only memories (EPROMs), flash memories, electrically erasable programmable read-only memories (EEPROMs), magnetic or optical cards, or any type of media suitable for storing electronic instructions, including programmable storage devices.

Embodiments of the disclosure may include components such as, but not limited to, a plurality of central processing units (CPU) or any other suitable multi-purpose or specific processors or controllers (e.g., controllers similar to the control circuitry 904), a plurality of input units, a plurality of output units, a plurality of memory units, and a plurality of storage units, etc. A system may additionally include other suitable hardware components and/or software components. In some embodiments, a system may include or may be, for example, a personal computer, a desktop computer, a mobile computer, a laptop computer, a notebook computer, a terminal, a workstation, a server computer, a Personal Digital Assistant (PDA) device, a tablet computer, a network device, or any other suitable computing device.

In some embodiments, a system may include or may be, for example, a plurality of components that include a respective plurality of central processing units, e.g., a plurality of CPUs as described, a plurality of CPUs embedded in an on-board system or network, a plurality of chips, FPGAs or SOCs, microprocessors, transceivers, microcontrollers, a plurality of computer or network devices, any other suitable computing device, and/or any combination thereof. For example, a system as described herein may include one or more devices such as the control circuitry 904.

The computing device 900 may include and/or communicate with one or more storage devices or databases 928. For example, the storage database 928 may correspond to a storage device (e.g., a semiconductor storage device, such as a solid-state drive (SSD)) of the computing device 900, a remote storage device or database, a cloud computing system, etc. The storage database 928 may store data accessible by one or more components of the systems described herein.

In some examples, the computing device 900 may implement an artificial intelligence (AI) engine configured to execute one or more AI or machine learning (ML) models, etc. trained using data (“training data”) obtained during operation. Various components of the training data, an AI engine, ML models, etc. may be stored within the computing device 900 or external to the computing device 900 (e.g., in a remote server, a cloud computing system, etc.).

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s). Moreover, this paragraph shall not negate that a base electrically connected to a collector-emitter through a transistor may be referred to as “directly coupled.”

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A circuit for bidirectional power switching, comprising:
a double-sided double-base bipolar junction transistor having a first base, a second base, a first collector-emitter terminal, and a second collector-emitter terminal;
a first field-effect transistor (FET) coupled to the first collector-emitter terminal; and
a second FET coupled to the second collector-emitter terminal,
wherein the double-sided double-base bipolar junction transistor, the first FET, and the second FET are integrated within a single package.

2. The circuit of claim 1, further comprising:
a third FET coupled to the first base, wherein the third FET is configured to, when active, drive a first signal on the first base; and
a fourth FET coupled to the second base, wherein the fourth FET is configured to, when active, drive a second signal on the second base,
wherein the third FET and the fourth FET are integrated within the single package.

3. The circuit of claim 2, wherein the package includes a plurality of external pins, wherein the plurality of external pins includes:
a first external pin electrically coupled to the first base and further coupled to a drain terminal of the third FET; and
a second external pin electrically coupled to the second base and further coupled to a drain terminal of the fourth FET.

4. The circuit of claim 3, wherein the first and second FETs are coupled in a cascode configuration to the first collector-emitter terminal and the second collector-emitter terminal, respectively, and wherein:
the first FET is coupled in between the first collector-emitter terminal and a third external pin of the plurality of external pins; and
the second FET is coupled between the second collector-emitter terminal and a fourth external pin of the plurality of external pins.

5. The circuit of claim 4, wherein the plurality of external pins further includes:
a fifth external pin coupled to a gate terminal of the third FET;
a sixth external pin coupled to a gate terminal of the fourth FET;
a seventh external pin coupled to a gate terminal of the first FET; and
an eighth external pin coupled to a gate terminal of the second FET.

6. The circuit of claim 1, wherein the package includes a lower portion and an upper portion overlapping with one another, wherein the double-sided double-base bipolar junction transistor is located in the package where the upper portion overlaps with the lower portion.

7. The circuit of claim 6, wherein the first FET, the first base, and the first collector-emitter terminal are implemented in the upper portion, and wherein the second FET, the second base, and the second collector-emitter terminal are implemented in the lower portion.

8. The circuit of claim 6, wherein the upper portion comprises a first substrate, and wherein the lower portion comprises a second substrate.

9. The circuit of claim 8, wherein the first substrate and the second substrate are ceramic substrates.

10. The circuit of claim 1, wherein the package comprises at least one active metal brazing substrate.

11. A system comprising:
a controller configured to generate a plurality of control signals; and
a bi-directional power switch coupled to receive the plurality of control signals, wherein the bi-directional power switch is implemented in a single electronic package that includes:
a double-sided double-base bipolar junction transistor having a first base, a second base, a first collector-emitter terminal, and a second collector-emitter terminal;
a first field-effect transistor (FET) electrically coupled between the first collector-emitter terminal and a first external pin of the electronic package; and
a second FET electrically coupled between the second collector-emitter terminal and a second external pin, wherein the first FET and the second FET are coupled in a cascode configuration with the double-sided double-base bipolar junction transistor,
wherein the controller is configured to generate the plurality of control signals to control respective states of the first FET, the second FET, and the double-sided double-base bipolar junction transistor, and wherein the bi-directional power switch is configured to operate in one of a plurality of modes depending on respective states of ones of the plurality of control signals.

12. The system of claim 11, wherein the bi-directional power switch further includes:
a third FET electrically coupled to the first base, wherein the third FET is configured to, when active, drive a first signal on the first base; and
a fourth FET coupled to the second base, wherein the fourth FET is configured to, when active, drive a second signal on the second base,
wherein the third FET and the fourth FET are integrated within the electronic package.

13. The system of claim 12, wherein the electronic package comprises a plurality of external pins including the first external pin and the second external pin, and wherein ones of a subset of the plurality of external pins are coupled to receive respective ones of the plurality of control signals, wherein the subset includes:
a third external pin electrically coupled to the first base and further coupled to a drain terminal of the third FET;
a fourth external pin electrically coupled to the second base and further coupled to a drain terminal of the fourth FET;
a fifth external pin electrically coupled to a gate terminal of the third FET;
a sixth external pin electrically coupled to a gate terminal of the fourth FET;
a seventh external pin electrically coupled to a gate terminal of the first FET; and
a eighth external pin electrically coupled to a gate terminal of the second FET.

14. The system of claim 11, wherein the electronic package comprises a first substrate and a second substrate that overlap one another, and wherein the double-sided double-base bipolar junction transistor is located in a region of overlap between the first substrate and the second substrate.

15. The system of claim 14, wherein the first substrate and the second substrate comprise ceramic substrates.

16. An electronic circuit package comprising:
a package body including a plurality of external terminals;
a double-sided double-base bipolar junction transistor disposed within the package body, the transistor having a first base, a second base, a first collector-emitter terminal, and a second collector-emitter terminal;
a first field-effect transistor (FET) disposed within the package body and electrically coupled between the first collector-emitter terminal and a first external terminal of the plurality of external terminals;
a second FET disposed within the package body and electrically coupled between the second collector-emitter terminal and a second external terminal of the plurality of external terminals; and
a first substrate and a second substrate disposed within the package body, wherein the double-sided double-base bipolar junction transistor is located in a region of overlap between the first substrate and the second substrate.

17. The electronic package of claim 16, wherein the first FET is disposed on the first substrate and the second FET is disposed on the second substrate.

18. The electronic package of claim 16, wherein the first substrate and the second substrate are ceramic substrates.

19. The electronic package of claim 16, wherein the first FET and the second FET are coupled in a cascode configuration with the double-sided double-base bipolar junction transistor.

20. The electronic circuit package of claim 16, wherein the package body comprises at least one active metal brazing substrate.
